(19) United States
(12) Patent Application Publication
(10) Pub. No.: US 2020/0186011 A1
(43) Pub. Date: Jun. 11, 2020

(54) ABNORMALITY DETECTING DEVICE FOR CURRENT SENSOR

(71) Applicant: SANDEN AUTOMOTIVE COMPONENTS CORPORATION, Isesaki-shi, Gunma (JP)

(72) Inventors: Takeo TSUKAMOTO, Isesaki-shi, Gunma (JP); Daisuke HIRONO, Isesaki-shi, Gunma (JP)

(21) Appl. No.: 16/063,961

(22) PCT Filed: Jan. 12, 2017
(86) PCT No.: PCT/JP2017/001828

§ 371 Date: Jun. 19, 2018

(30) Foreign Application Priority Data
Jan. 22, 2016 (JP) 2016-010991

(51) Int. Cl. H02K 11/25; H02P 29/032; G01R 19/00; H02K 11/33

(52) U.S. Cl. CPC H02K 11/25; H02K 11/33; G01R 19/0038; H02P 29/032

(57) ABSTRACT

An abnormality detecting device for a current sensor detecting whether a single current sensor provided in an inverter which supplies electric power to a motor driving a compressor is abnormal detects phase currents of the motor based on an output signal of the current sensor, estimates an estimated phase current value of the phase currents of the motor based on at least one of a discharge pressure and a suction pressure of the compressor and a rotational speed of the motor, compares detected values of the phase currents with an estimated phase current value of the phase currents, and then detects whether the current sensor is abnormal based on the comparison result.

### TECHNICAL FIELD

The present invention relates to an abnormality detecting device for a current sensor.

### BACKGROUND ART

A known abnormality detecting device for a current sensor performs abnormality detection in the current sensor by comparing output signals of a plurality of current sensors when the plurality of current sensors is provided in an inverter, for example, when the current sensor detecting a phase current of a motor is provided for each phase (for example, refer to Patent Document 1).

### REFERENCE DOCUMENT LIST

### Patent Document

Patent Document 1: JP 2015-192582 A

### SUMMARY OF THE INVENTION

### Problems to be Solved by the Invention

In a case in which a plurality of current sensors is provided in an inverter, there is a possibility of causing increase in the size of the inverter and in product cost, and thus, a phase current is detected by a single current sensor. Accordingly, even in a case in which the single current sensor is provided in the inverter, a technique capable of detecting abnormalities of the single current sensor has been desired.

In view of the above-described conventional problems, it is an object of the present invention to provide an abnormality detecting device for a current sensor, the abnormality detecting capability of which is improved so as to be able to detect abnormalities of a single current sensor detecting a phase current of a motor even in a case in which the single current sensor is provided in an inverter.

### Means for Solving the Problems

In order to achieve the object, an abnormality detecting device for a current sensor according to a first aspect of the present invention is supposed to detect whether the current sensor provided in an inverter supplying electric power to a motor driving a compressor is abnormal, and the abnormality detecting device for the current sensor detects a phase current of the motor based on an output signal from the current sensor, estimates the phase current of the motor based on at least one of the discharge pressure and the suction pressure of the compressor and the rotational speed of the motor, compares the detected value of the phase current with the estimated value of the phase current, and then detects whether the current sensor is abnormal based on the result of the comparison.

An abnormality detecting device for a current sensor according to a second aspect of the present invention is supposed to detect whether the current sensor provided in an inverter supplying electric power to a motor is abnormal, and the abnormality detecting device for the current sensor detects a phase current of the motor based on an output signal from the current sensor, estimates the phase current based on an output signal from the first temperature sensor provided in a switching element of the inverter or in the vicinity thereof, compares the detected value of the phase current with the estimated value of the phase current, and then detects whether the current sensor is abnormal based on the result of the comparison.

An abnormality detecting device for a current sensor according to a third aspect of the present invention is supposed to detect whether the current sensor provided in an inverter supplying electric power to a motor is abnormal, and the abnormality detecting device for the current sensor estimates a phase current based on an output signal from a first temperature sensor provided in a switching element of the inverter or in the vicinity thereof, and then detects whether the current sensor is abnormal based on the estimated value of the phase current and a temperature relating to the current sensor detected based on an output signal from a second temperature sensor provided in the current sensor or in the vicinity thereof.

An abnormality detecting device for a current sensor according to a fourth aspect of the present invention is supposed to detect whether the current sensor provided in an inverter supplying electric power to a motor is abnormal, and the abnormality detecting device for the current sensor detects whether the current sensor is abnormal based on a temperature relating to the current sensor detected based on an output signal from a temperature sensor provided in the current sensor or in the vicinity thereof in a state in which energization to the motor is held in a predetermined pattern before the motor is driven to rotate.

### Effects of the Invention

The abnormality detecting device for the current sensor of the present invention improves the abnormality detecting capability to be able to detect abnormalities of the single current sensor which detects the phase current of the motor even in a case in which the single current sensor is provided in the inverter.

### BRIEF DESCRIPTION OF THE DRAWINGS

FIG. 1 is a block diagram illustrating a refrigeration cycle according to the first embodiment.

FIG. 2 is a block circuit diagram illustrating a motor system according to the first embodiment.

FIGS. 3A and 3B are a circuit diagram explaining a phase current detecting method according to the first embodiment.

FIG. 4 is a phase current specifying table according to the first embodiment.

FIG. 5 is a diagram illustrating the relationship between a discharge pressure and a motor current according to the first embodiment.

FIG. 6 is a diagram illustrating the relationship between rotational speed and the motor current according to the first embodiment.

FIG. 7 is a diagram illustrating relationships among the rotational speed, discharge pressure, and the motor current according to the first embodiment.

FIG. 8 is a diagram illustrating relationships among a suction pressure, the discharge pressure, and the motor current according to the first embodiment.

FIG. 9 is a diagram illustrating the relationship between the suction pressure and the motor current according to the first embodiment.

FIG. 10 is a block circuit diagram illustrating the motor system according to the second embodiment.

FIG. 11 is a diagram illustrating the relationship between the temperature in the vicinity of a switching element and the motor current according to the second embodiment.

FIG. 12 is a block circuit diagram illustrating the motor system according to the third embodiment.

FIG. 13 is a diagram illustrating the relationship between the temperature relating to the current sensor and the motor current, and the relationship between the temperature relating to the switching element and the motor current according to the third embodiment.

FIG. 14 is a block circuit diagram illustrating the motor system according to the fourth embodiment.

FIG. 15 is a diagram illustrating time changes of the temperature relating to the current sensor according to the fourth embodiment.

### MODE FOR CARRYING OUT THE INVENTION

Hereinafter, the embodiments for carrying out the present invention are described in detail with reference to the attached drawings.

### First Embodiment

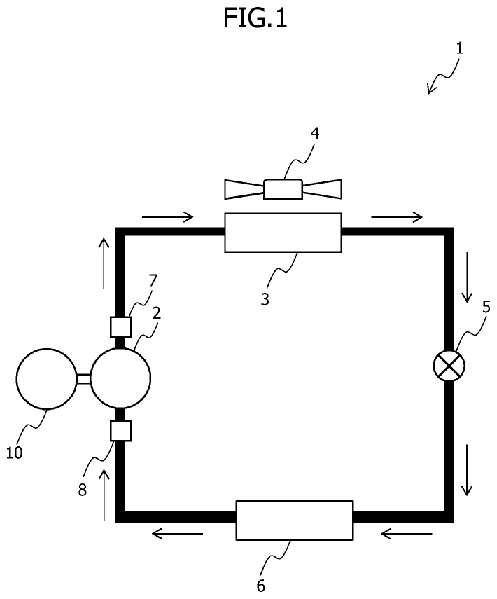

FIG. 1 illustrates an example of a refrigeration cycle to which an abnormality detecting device for the current sensor according to the first embodiment of the present invention is applied.

### (Refrigeration Cycle)

In a refrigeration cycle 1 of circulating a refrigerant in a refrigerating device and the like, a vaporized refrigerant is compressed by a compressor 2 to increase the temperature, the compressed and temperature-raised refrigerant is caused to dissipate heat and condensed by forced cooling, for example, rotating an electric fan 4 in a condenser 3, to be formed into a liquid, the liquid is partially evaporated by being decompressed and expanded with an expansion valve 5, and then the remaining liquid is vaporized by taking the heat from the ambient air with an evaporator 6. The refrigerant vaporized with the evaporator 6 is compressed again by the compressor 2. The refrigerant circulates by repeating the above.

In a discharge port of the compressor 2, a discharge pressure sensor 7 detecting the discharge pressure of the refrigerant is provided. In a suction port of the compressor 2, a suction pressure sensor 8 detecting the suction pressure of the refrigerant is provided. The compressor 2 is driven by the shaft output of a motor 10 described later in detail.

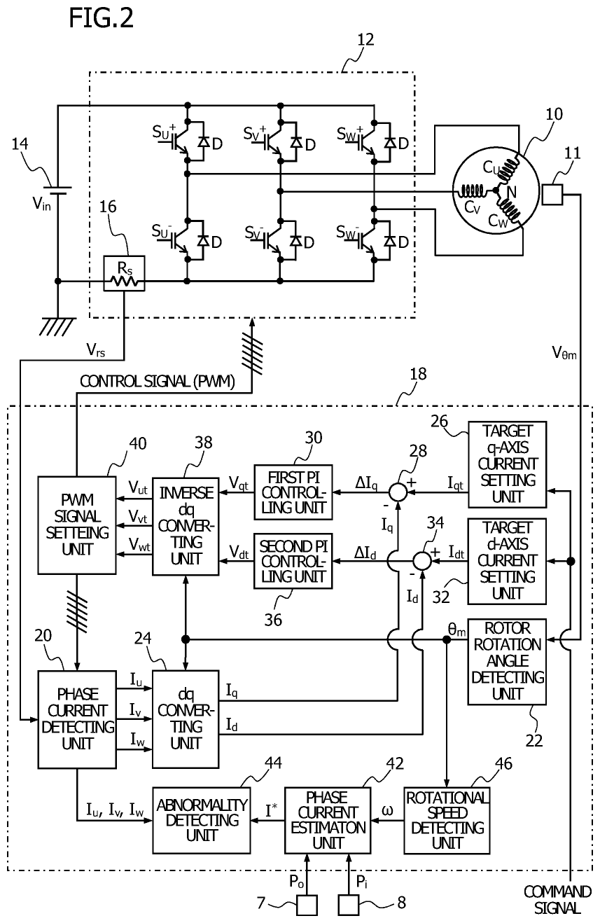

FIG. 2 illustrates an example of a motor system including the motor 10 and a drive control system therefor.

### (Motor)

The motor 10 is a three-phase brushless motor and has a stator (not illustrated) including a three-phase coil of a U-phase coil C_{U}, a V-phase coil C_{V}, and a W-phase coil C_{W} and a rotor (not illustrated) including a permanent magnet. One end of each of the U-phase coil C_{U}, the V-phase coil C_{V}, and the W-phase coil C_{W} is electrically connected at a neutral point N so that the U-phase coil C_{U}, the V-phase coil C_{V}, and the W-phase coil C_{W} are star-connected and the other end of each of the U-phase coil C_{U}, the V-phase coil C_{V}, and the W-phase coil C_{W} is connected to an inverter 12 described later. Moreover, in the vicinity of the rotor of the motor 10, a rotational position sensor 11 outputting an output signal V_{θm} relating to the rotational position of the rotor, such as a hall element converting a magnetic variation by the rotation of the rotor of the motor 10 to an electric signal, for example, is provided. Even when the stator of the motor 10 includes a delta connection, the abnormality detecting device for the current sensor according to the present invention is applicable.

### (Inverter)

The inverter 12 supplying electric power from a DC power supply 14 to the motor 10 has a three-phase bridge circuit. In the three-phase bridge circuit, with respect to each phase of the U-phase, the V-phase, and the W-phase, two switching elements are connected in series between the high potential side and the low potential side of the DC power supply 14 and a diode D is connected antiparallel to each switching element. With respect to the U-phase, the end of the U-phase coil C_{U} is connected to a location between a switching element S_{U}⁺ on the upper arm and a switching element S_{U}⁻ on the lower arm. With respect to the V-phase, the end of the V-phase coil C_{V} is connected to a location between a switching element S_{V}⁺ on the upper arm and a switching element S_{V}⁻ on the lower arm. With respect to the W-phase, the end of the W-phase coil C_{W} is connected to a location between a switching element S_{W}⁺ on the upper arm and a switching element S_{W}⁻ on the lower arm. For the switching element, not only IGBT (Insulated Gate Bipolar Transistor) used in this embodiment but a semiconductor element, such as MOSFET (Metal-Oxide-Semiconductor Field-Effect Transistor), may be used.

Moreover, in the inverter 12, one current sensor 16 detecting a motor current of the motor 10 is installed alone between the switching elements S_{U}⁻, S_{V}⁻, and S_{W}⁻ on the lower arm and the low potential side of the DC power supply 14. The current sensor 16 has a shunt resistor Rs through which the motor current flows and an operational amplifier (not illustrated) amplifying a potential difference between both ends of the shunt resistor Rs and outputting the amplified potential difference. The current sensor 16 is a shunt resistor type current detecting unit which outputs an output signal Vrs of the operational amplifier.

In this embodiment, the current sensor 16 may be not only the shunt resistor type current detecting unit, but may also be a current sensor including a hall element or a transformer or the like.

### (Motor Control Device)

A motor control device 18 controlling the motor 10 A/D (Analog/Digital)-converts, as appropriate, the output signal Vrs of the current sensor 16, the output signal V_{θm} of the rotational position sensor 11, and a command signal from an external host control device (not illustrated), and then generates a PWM signal as a control signal to each control terminal of the switching elements S_{U}⁺, S_{U}⁻, S_{V}⁺, S_{V}⁻, S_{W}⁺, and S_{W}⁻ of the inverter 12 based on the converted digital value to output the generated PWM signal. Thus, sine wave energization (180° energization) is performed to the three-phase coil of the U-phase coil C_{U}, the V-phase coil C_{V}, and the W-phase coil C_{W}. Although not illustrated, the motor control device 18 is described on the premise that the motor control device 18 includes a computer and memory units, such as a RAM (Random Access Memory) and a ROM (Read Only Memory), therein, and each function, described later, in the motor control device 18 is executed by a computer which is operated by reading programs stored in advance. However, the motor control device 18 is not limited thereto and each function can be partially or entirely executed according to the hardware configuration.

The motor control device 18 has functions specified by a phase current detecting unit 20, a rotor rotation angle detecting unit 22, a dq converting unit 24, a target q-axis current setting unit 26, a first adding and subtracting unit 28, a first PI controlling unit 30, a target d-axis current setting unit 32, a second adding and subtracting unit 34, a second PI controlling unit 36, an inverse dq converting unit 38, and a PWM signal setting unit 40.

The phase current detecting unit 20 detects phase currents Iu, Iv, and Iw based on the output signal Vrs of the current sensor 16, the known resistance value of the shunt resistor Rs, and the PWM signal set in the PWM signal setting unit 40 described later. A specific detecting method of the phase currents Iu, Iv, and Iw is described later.

The rotor rotation angle detecting unit 22 detects the rotation angle θm of the rotor of the motor 10 based on the output signal V_{θm} of the rotational position sensor 11.

The dq converting unit 24 converts the phase currents Iu, Iv, and Iw detected by the phase current detecting unit 20 to a d-axis current value Id and a q-axis current value Iq of the dq coordinate system using the rotor position Om detected by the rotor rotation angle detecting unit 22. In the dq coordinate, the field direction rotating synchronizing with the rotor of the motor 10 is defined as the d-axis and the torque generation direction orthogonal to the d-axis is defined as the q-axis.

The target q-axis current setting unit 26 sets a target q-axis current value Iqt based on the command signal from the host controlling device or by the other known methods. In order to perform current feedback control, the first adding and subtracting unit 28 calculates a q-axis current deviation ΔIq which is a deviation between the target q-axis current value Iqt and the q-axis current value Iq, and then, the first PI controlling unit 30 calculates a q-axis applied setting voltage value Vqt by performing PI control based on the q-axis current deviation ΔIq.

The target d-axis current setting unit 32 sets a target d-axis current value Idt based on the command signal from the host control device or by the other known methods. In order to perform current feedback control, the second adding and subtracting unit 34 calculates a d-axis current deviation ΔId which is a deviation between the target d-axis current value Idt and the d-axis current value Id, and then, the second PI control unit 36 calculates a d-axis applied setting voltage value Vdt by performing PI control based on the d-axis current deviation ΔId.

The inverse dq converting unit 38 converts, using the rotor position θm, the q-axis applied setting voltage value Vqt and the d-axis applied setting voltage value Vdt of the dq coordinate system to applied setting voltage values of a three-phase coordinate system of a U-phase applied setting voltage value Vut to be applied to the U-phase coil C_{U}, a V-phase applied setting voltage value Vvt to be applied to the V-phase coil C_{V}, and a W-phase applied setting voltage value Vwt to be applied to the W-phase coil C_{W}.

The PWM signal setting unit 40 sets the duty regulating a ratio between ON and OFF of each switching element with respect to six PWM signals to be output to the control terminals of the switching elements U⁺, U⁻, V⁺, V⁻, W⁺, and W⁻ provided in the inverter 12 based on a power supply voltage value Vin of the DC power supply 14, the U-phase applied setting voltage value Vut, the V-phase applied setting voltage value Vvt, and the W-phase applied setting voltage value Vwt. Thus, sine wave energization (180° energization) is performed to the three-phase coil of the U-phase coil C_{U}, the V-phase coil C_{V}, and the W-phase coil C_{W}.

### (Phase Current Detecting Method)

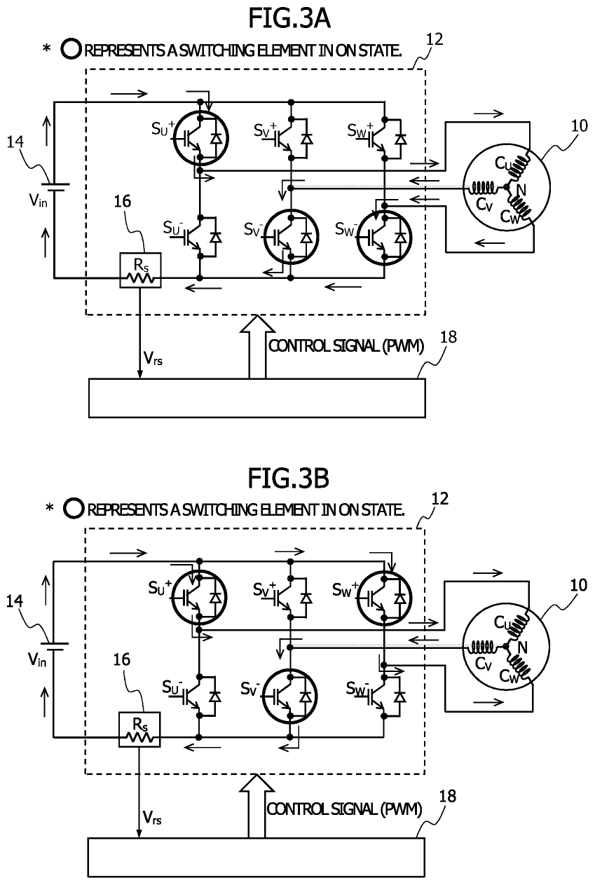

FIGS. 3A and 3B are a circuit diagram for explaining a phase current detecting method in the phase current detecting unit 20. The phase current detecting method in the phase current detecting unit 20 is described with reference to FIGS. 3A and 3B.

In FIG. 3A, the switching element S_{U}⁺, the switching element S_{V}⁻, and the switching element S_{W}⁻ are in the ON state and the switching element S_{U}⁻, the switching element S_{V}⁺, and the switching element S_{W}⁺ are in the OFF state. In such ON and OFF states of the switching elements, the current flows from the DC power supply 14 through the switching element S_{U}⁺ of the inverter 12 to the U-phase coil C_{U} of the motor 10, and at the neutral point N, the current is divided to flow in the two directions of a path in which some of the current flows through the V-phase coil C_{V} and a path in which the remaining current flows through the W-phase coil C_{W}. Some of the current flowing through the V-phase coil C_{V} from the neutral point N flows through the switching element S_{V}⁻, and the remaining current flowing through the W-phase coil C_{W} from the neutral point N flows through the switching element S_{W}⁻. The currents flowing through the two paths merge before flowing through the shunt resistor Rs to return to the DC power supply 14. Thus, the current flowing through the shunt resistor Rs of the current sensor 16 corresponds to a U-phase current Iu flowing towards the neutral point N. The U-phase current Iu can be detected based on the output signal Vrs of the current sensor 16 in such flowing state of the current and the known resistance of the shunt resistor Rs.

In FIG. 3B, the switching element S_{U}⁺, the switching element S_{V}⁻, and the switching element S_{W}⁺ are in the ON state and the switching element S_{U}⁻, the switching element S_{V}⁺, and the switching element S_{W}⁻ are in the OFF state. In such ON and OFF states of the switching elements, the current flowing into the inverter 12 from the DC power supply 14 is divided to flow in the two directions of a path in which some of the current flows through the switching element S_{U}⁺ and a path in which the remaining current flows through the switching element S_{W}⁺, and then the currents merge at the neutral point N of the motor 10. The current merged at the neutral point N flows through the V-phase coil C_{V} and the shunt resistor Rs in this order to return to the DC power supply 14. Thus, the motor current flowing through the shunt resistor Rs of the current sensor 16 corresponds to a V-phase current Iv flowing towards the inverter 12 from the neutral point N. The V-phase current Iv can be detected based on the output signal Vrs of the current sensor 16 in such flowing state of the current and the known resistance of the shunt resistor Rs.

Accordingly, when the ON and OFF states of the switching elements S_{U}⁺, S_{U}⁻, S_{V}⁺, S_{V}⁻, S_{W}⁺, and S_{W}⁻ are determined, the motor current detected based on the output signal Vrs of the current sensor 16 is specified to be any one of the phase currents Iu, Iv, and Iw of the U-phase, the V-phase, and the W-phase together with the current direction in the phase current detection unit 20.

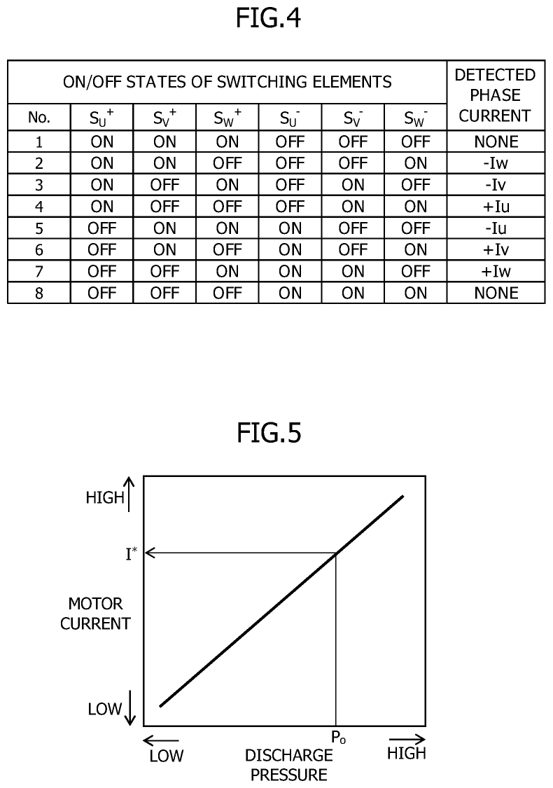

FIG. 4 illustrates a phase current specifying table illustrating the relationship between the ON and OFF states of the switching elements S_{U}⁺, S_{U}⁻, S_{V}⁺, S_{V}⁻, S_{W}⁺, and S_{W}⁻ and the phase currents Iu, Iv, and Iw detected corresponding to the states.

The phase current specifying table illustrates eight switching patterns which are combinations of the ON and OFF states of the switching elements S_{U}⁺, S_{U}⁻, S_{V}⁺, S_{V}⁻, S_{W}⁺, and S_{W}⁻. The rightmost column of the table specify the detected phase currents Iu, Iv, and Iw which correspond to the switching patterns, except the switching pattern in which the switching elements S_{U}⁺, S_{V}⁺, and S_{W}⁺ are all turned ON and the switching elements S_{U}⁻, S_{V}⁻, and S_{W} are all turned OFF and the switching pattern in which the switching elements S_{U}⁺, S_{V}⁺, and S_{W}⁺ are all turned OFF and the switching elements S_{U}⁻, S_{V}⁻, and S_{W} are all turned ON, with a plus (+) sign indicating a direction in which the phase currents Iu, Iv, and Iw flow towards the neutral point N and a minus (−) sign indicating a direction in which the phase currents Iu, Iv, and Iw flow from the neutral point N to the inverter 12.

The phase current detection unit 20 prestores the above-described phase current specifying table and determines to which switching pattern of the eight switching patterns the ON and OFF states of the switching elements S_{U}⁺, S_{U}⁻, S_{V}⁺, S_{V}⁻, S_{W}⁺, and S_{W}⁻ correspond by referring to the phase current specifying table based on the PWM signal set in the PWM signal setting unit 40. Then, based on the switching pattern which is determined to correspond to the ON and OFF state, the phase current detection unit 20 specifies to which phase currents Iu, Iv, and Iw of the U-phase, the V-phase, and the W-phase the motor current detected based on the output signal Vrs of the current sensor 16 correspond, together with the current direction of the corresponding phase current. Thus, the phase current detection unit 20 detects the phase currents Iu, Iv, and Iw. In the following description, the phase currents Iu, Iv, and Iw indicate the magnitude of the current not relating to the current direction and are positive values. The motor current indicates the magnitude of the current to be detected by the current sensor 16 or the magnitude of the current estimated to be detected by the current sensor 16 and is a positive value not relating to the current direction.

### (Abnormality Detecting Device for Current Sensor)

As described above, the phase current detecting unit 20 detects the phase currents Iu, Iv, and Iw also including the current direction based on the output signal Vrs of the single current sensor 16, the known resistance value of the shunt resistor Rs, and the PWM signal set in the PWM signal setting unit 40. However, the phase current detecting unit 20 cannot detect whether any of a plurality of current sensors is abnormal by comparing output signals of the current sensors with each other as in the case in which the plurality of current sensors is provided in the inverter 12.

Therefore, even in a case in which the single current sensor 16 is provided in the inverter 12, in the motor control device 18, a phase current estimation unit 42 and an abnormality detecting unit 44, which are parts of the motor control device 18, have a function as an abnormality detecting device for the current sensor 16 capable of detecting whether the current sensor 16 is abnormal. The abnormality detecting unit 44 compares the detected values of the phase currents Iu, Iv, and Iw detected by the phase current detecting unit 20 with an estimated phase current value I* (≥0) estimated as an estimated value of the phase currents Iu, Iv, and Iw by the phase current estimating unit 42 when the phase currents Iu, Iv, and Iw are detected, and then, based on the comparison result, the abnormality detecting unit 44 detects whether the current sensor 16 is abnormal. For example, when an absolute value of a deviation between the detected values of the phase currents Iu, Iv, and Iw and the estimated phase current value I* is determined to be equal to or greater than a predetermined value, the abnormality detecting unit 44 can detect that the current sensor 16 is abnormal, and when the absolute value of the deviation between the detected values of the phase currents Iu, Iv, and Iw and the estimated phase current value I* is determined to be lower than the predetermined value, the abnormality detecting unit 44 can detect that the current sensor 16 is normal.

The phase current estimation unit 42 estimates the estimated phase current value I* based on at least one of the discharge pressure and the suction pressure of the compressor 2 and the rotational speed of the rotor. As methods for estimating the estimated phase current value I* in the phase current estimation unit 42, the following five methods are mentioned, for example.

First, as illustrated in FIG. 5, in the first estimation method, the relationship in which the motor current is substantially proportional to the discharge pressure of the compressor 2 is pre-digitized by an experiment, a simulation, or the like, and then the first current data table in which the discharge pressure and the motor current are associated with each other is stored in the ROM or the like. Then, the corresponding motor current is defined as the estimated phase current value I* with reference to the first current data table based on a detected value of the discharge pressure Po detected by the discharge pressure sensor 7.

The motor current in the first current data table has the same value for the same discharge pressure irrespective of which one of the phase currents Iu, Iv, and Iw the motor current corresponds to. However, in view of the fact that there are electrical variations between the phase coils C_{U}, C_{V}, and C_{W}, between the switching elements S_{U}⁺, S_{U}⁻, S_{V}⁺, S_{W}⁺, and S_{W}⁻, or the like, the motor current may be a different value to the same discharge pressure according to which of the phase currents Iu, Iv, and Iw the motor current corresponds to (the same applies to the following second to fifth current data tables.).

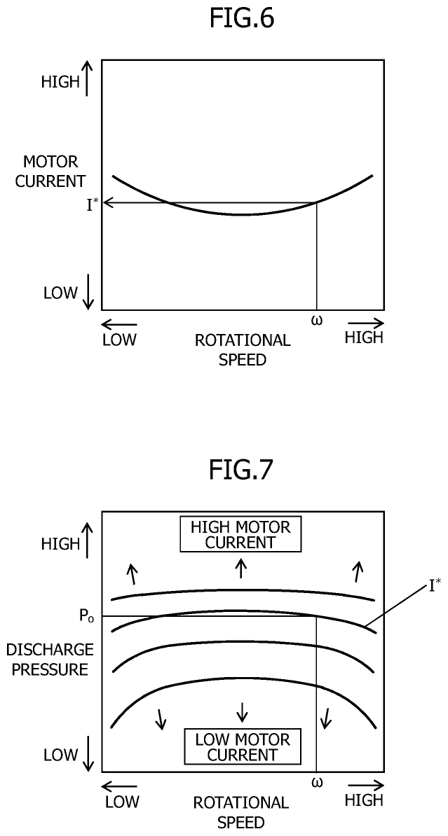

As illustrated in FIG. 6, in the second estimation method, the relationship in which, as the rotational speed of the rotor increases, the motor current decreases once, and then increases is pre-digitized by an experiment or a simulation, and then the second current data table in which the rotational speed and the motor current are associated with each other is stored in the ROM or the like. With respect to this estimation method, the motor control device 18 further has a rotational speed detecting unit 46 detecting a rotational speed co of the rotor with a relational expression of ω=dθm/dt or the like, based on the rotor position θm detected by the rotor rotation angle detecting unit 22. Then, the corresponding motor current is defined as the estimated phase current value I* with reference to the second current data table based on the rotational speed co of the rotor detected by the rotational speed detecting unit 46.

As illustrated in FIG. 7, in the third estimation method, the relationship in which the motor current increases as the discharge pressure of the compressor 2 increases (refer to FIG. 5) and as the rotational speed of the rotor increases, the motor current decreases once, and then increases (refer to FIG. 6) is pre-digitized by an experiment or a simulation, and then the third current data table in which the rotational speed, the discharge pressure, and the motor current are associated with each other is stored in the ROM or the like. With respect to this estimation method, the motor control device 18 further has the rotational speed detecting unit 46 described above. Then, the corresponding motor current is defined as the estimated phase current value I* with reference to the third current data table based on the detected value of the discharge pressure Po detected by the discharge pressure sensor 7 and the rotational speed co of the rotor detected by the rotational speed detecting unit 46. Thus, parameters specifying the motor current increase as compared with the case in which the estimated phase current value I* is estimated by either the first or second estimation method, and thus, the estimated phase current value I* is estimated with good accuracy.

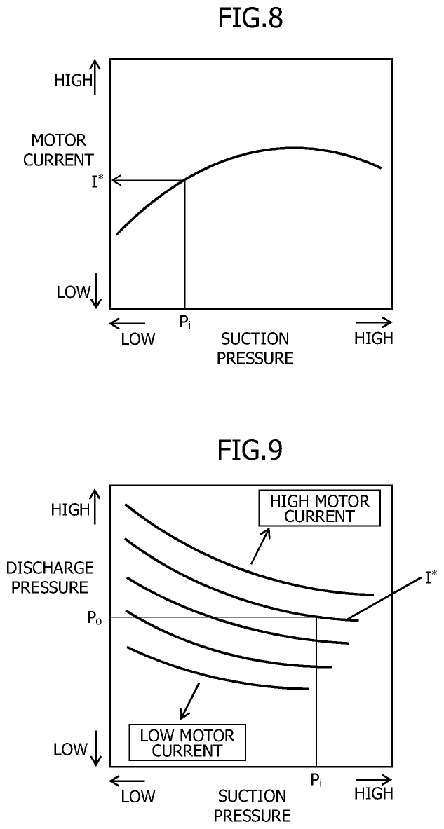

As illustrated in FIG. 8, in the fourth estimation method, the relationship in which as the suction pressure of the compressor 2 increases, the motor current increases once, and then decreases is pre-digitized by an experiment or a simulation, and then the fourth current data table in which the suction pressure and the motor current are associated with each other is stored in the ROM or the like. Then, the corresponding motor current is defined as the estimated phase current value I* with reference to the fourth current data table based on a detected value of the suction pressure Pi of the compressor 2 detected by the suction pressure sensor 8.

As illustrated in FIG. 9, in the fifth estimation method, the relationship in which as the discharge pressure of the compressor 2 increases, the motor current increases (refer to FIG. 5) and as the suction pressure of the compressor 2 increases, the motor current increases once, and then decreases (refer to FIG. 8) is pre-digitized by an experiment or a simulation, and then the fifth current data table in which the suction pressure, the discharge pressure, and the motor current are associated with each other is stored in the ROM or the like. Then, the estimated phase current value I* is estimated from the corresponding motor current with reference to the fifth current data table based on the detected value of the suction pressure Pi detected by the suction pressure sensor 8 and the detected value of the discharge pressure Po detected by the discharge pressure sensor 7. Thus, parameters specifying the motor current increase as compared with the case in which the estimated phase current value I* is estimated by either the first or fourth estimation method, and thus, the estimated phase current value I* is estimated with good accuracy.

In the first to third estimation methods, it is not necessary to provide the suction pressure sensor 8. In the first, fourth, and fifth estimation methods, the rotational speed detecting unit 46 is unnecessary in the motor control device 18. In the second and fifth estimation methods, it is not necessary to provide the discharge pressure sensor 7.

Such an abnormality detecting device for the current sensor 16 according to the first embodiment compares, in the abnormality detecting unit 44, the detected values of the phase currents Iu, Iv, and Iw detected by the phase current detecting unit 20 and the estimated phase current value I* estimated by the phase current estimation unit 42 when the phase currents Iu, Iv, and Iw are detected, and then detects whether the current sensor 16 is abnormal based on the comparison result. Thus, even when the single current sensor 16 is provided in the inverter 12, abnormalities of the current sensor 16 are detectable. Moreover, even in a case in which one current sensor is provided for each phase, the abnormality detecting method for the single current sensor 16 of this embodiment is applicable. Therefore, the abnormality detection capability is improved as compared with an abnormality detecting device for a current sensor which detects abnormalities by comparing output signals of a plurality of current sensors with each other.

### Second Embodiment

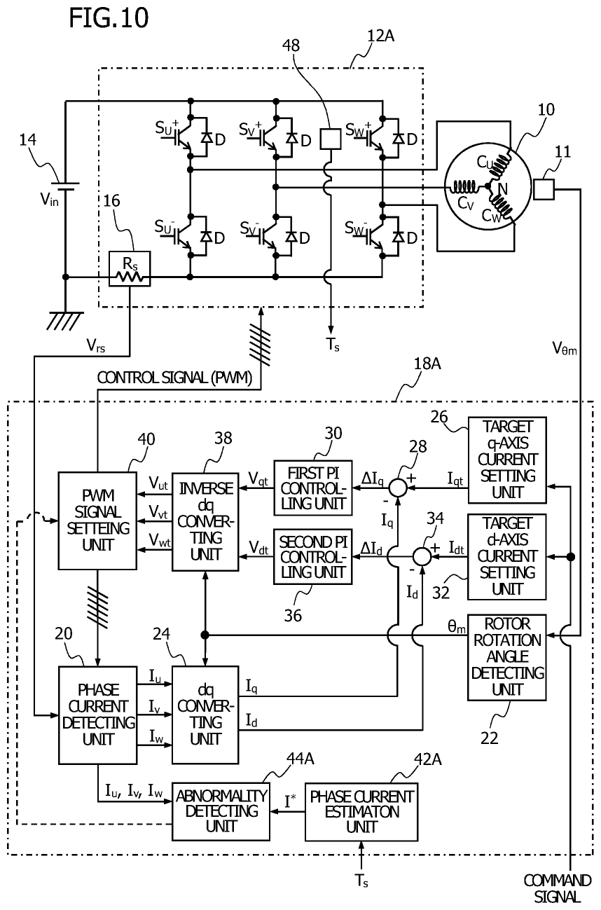

FIG. 10 is a block circuit diagram illustrating an example of a motor system to which an abnormality detecting device for the current sensor 16 according to a second embodiment of the present invention is applied. The same configurations as those of the first embodiment are designated by the same reference symbols, and the description thereof is omitted as much as possible (the same will be applied hereinafter).

In an inverter 12A, the first temperature sensor 48, such as a thermistor, is further provided in at least one of the switching elements S_{U}⁺, S_{U}⁻, S_{V}⁺, S_{V}⁻, S_{W}⁺, and S_{W}⁻ or in the vicinity thereof. Hereinafter, the first temperature sensor 48 is provided in the switching element S_{W}⁺ or in the vicinity of the switching element S_{W}⁺ and detects a temperature Ts of the switching element S_{W}⁺ or around the switching element S_{W}⁺ (hereinafter referred to as “temperature relating to the switching element S_{W}⁺”) for convenience of description.

In a motor control device 18A, a phase current estimation unit 42A and an abnormality detecting unit 44A, which are parts of the motor control device 18A, have a function as an abnormality detecting device for the current sensor 16.

Although the phase current estimation unit 42 of the motor control device 18 according to the first embodiment estimates the estimated phase current value I* based on at least one of the discharge pressure and the suction pressure of the compressor 2 and the rotational speed of the rotor, the phase current estimation unit 42A of the motor control device 18A according to the second embodiment estimates the phase current value I* based on the temperature Ts relating to the switching element S_{W}⁺ detected from an output signal of the first temperature sensor 48.

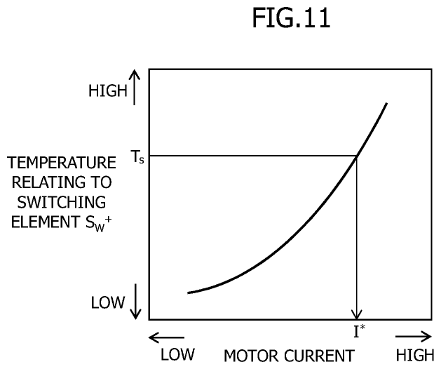

For example, as illustrated in FIG. 11, the relationship in which the temperature relating to the switching element S_{W}⁺ changes substantially in a quadratic function manner to the motor current under the influence of Joule heat generated in the ON-resistance of the switching element S_{W}⁺ is pre-digitized by an experiment or a simulation, and then, the phase current estimation unit 42A stores the sixth current data table in which the motor current and the temperature relating to the switching element S_{W}⁺ are associated with each other in a ROM or the like. Since the first temperature sensor 48 detects the temperature Ts relating to the switching element S_{W}⁺, the temperature relating to the switching element S_{W}⁺ in the sixth current data table may be associated with the motor current which corresponds to the W-phase current Iw. Then, the corresponding motor current is defined as the estimated phase current value I* with reference to the sixth current data table based on the temperature Ts relating to the switching element S_{W}⁺ detected by the first temperature sensor 48. Thus, the phase current estimation unit 42A estimates the estimated phase current value I*.

The abnormality detecting unit 44A compares the detected values of the phase currents Iu, Iv, and Iw detected by the phase current detecting unit 20 with the estimated phase current value I* estimated by the phase current estimation unit 42A when the phase currents Iu, Iv, and Iw are detected, and then detects whether the current sensor 16 is abnormal based on the comparison result. For example, the abnormality detecting unit 44A detects whether the current sensor 16 is abnormal by determining whether an absolute value of a deviation between the detected values of the phase current values Iu, Iv, and Iw and the estimated phase current value I* is equal to or greater than a predetermined value. As described above, when the temperature relating to the switching element S_{W}⁺ in the sixth current data table is associated with the motor current which corresponds to the W-phase current Iw, the abnormality detecting unit 44A may compare the detected value of the W-phase current Iw detected by the phase current detecting unit 20 with the estimated phase current value I* estimated by the phase current estimation unit 42A when the W-phase current Iw is detected by the phase current detecting unit 20.

The abnormality detection of the current sensor 16 in the abnormality detecting unit 44A may be performed not only when the motor control device 18A generates and outputs a PWM signal to each control terminal of the switching elements S_{U}⁺, S_{U}⁻, S_{V}⁺, S_{V}⁻, S_{W}⁺, and S_{W}⁻ based on a command signal or the like, and then performs sine wave energization to the three-phase coil C_{U}, C_{V}, and C_{W} to rotationally drive the motor 10 but also before the motor 10 is rotationally driven.

When the abnormality detection of the current sensor 16 is performed before the motor 10 is rotationally driven, the abnormality detecting unit 44A directs to the PWM signal setting unit 40 to forcibly hold the duty of the PWM signals to be output to the switching elements S_{U}⁺, S_{U}⁻, S_{V}⁺, S_{V}⁻, S_{W}⁺, and S_{W}⁻ at a predetermined ratio irrespective of the U-phase applied setting voltage value Vut, the V-phase applied setting voltage value Vvt, and the W-phase applied setting voltage value Vwt. Thus, an energization path of the inverter 12A and the level of the motor current to the motor 10 are made constant.

For example, when the temperature relating to the switching element S_{W}⁺ in the sixth current data table is associated with the motor current which corresponds to the W-phase current Iw as described above, the abnormality detecting unit 44A may direct to the PWM signal setting unit 40 to hold the energization to the motor 10 in the following predetermined pattern to thereby energize the motor 10 by the motor current which corresponds to the W-phase current Iw. More specifically, the abnormality detecting unit 44A directs to the PWM signal setting unit 40 to hold the duty of the PWM signals to be output to the switching element S_{U}⁻, the switching element S_{V}⁻, and the switching element S_{W}⁺ at a predetermined ratio and hold the duty of the PWM signals to be output to the switching element S_{U}⁺, the switching element S_{V}⁺, and the switching element S_{W} at 0% (refer to the switching pattern No. 7 of FIG. 4) or to hold the duty of the PWM signals to be output to the switching element S_{U}⁻, the switching element S_{V}⁻, and the switching element S_{W}⁺ at 0% and hold the duty of the PWM signals to be output to the switching element S_{U}⁺, the switching element S_{V}⁺, and the switching element S_{W} at a predetermined ratio (refer to the switching pattern No. 2 of FIG. 4).

When the abnormality detection of the current sensor 16 is performed before the motor 10 is rotationally driven, the temperature relating to the switching element S_{W}⁺ in the sixth current data table may be a temperature when the energization state by the motor current specified in the sixth current data table continues for a predetermined period of time, for example, when the switching element S_{W}⁺ is estimated to reach the thermal equilibrium state. In this case, the phase current estimation unit 42A estimates the estimated phase current value I* using the temperature Ts relating to the switching element S_{W}⁺ detected by the first temperature sensor 48 when the above-described predetermined time has passed.

For the estimation of the estimated phase current value I* in the phase current estimation unit 42A, the discharge pressure sensor 7 and the suction pressure sensor 8 used in the first embodiment are not required. Thus, in a case in which a driving target of the motor 10 is not the compressor 2 in the refrigeration cycle 1, the abnormality detecting device for the current sensor 16 according to this embodiment is applicable.

Such an abnormality detecting device for the current sensor 16 according to the second embodiment is capable of detecting abnormalities of the current sensor 16 even in a case in which the single current sensor 16 is provided in the inverter 12A as with the first embodiment. Moreover, even in a case in which one current sensor is provided for each phase, the abnormality detecting method for the single current sensor 16 of this embodiment is applicable. Thus, the abnormality detection capability is improved as compared with an abnormality detecting device for a current sensor which detects abnormalities by comparing output signals of a plurality of current sensors with each other.

### Third Embodiment

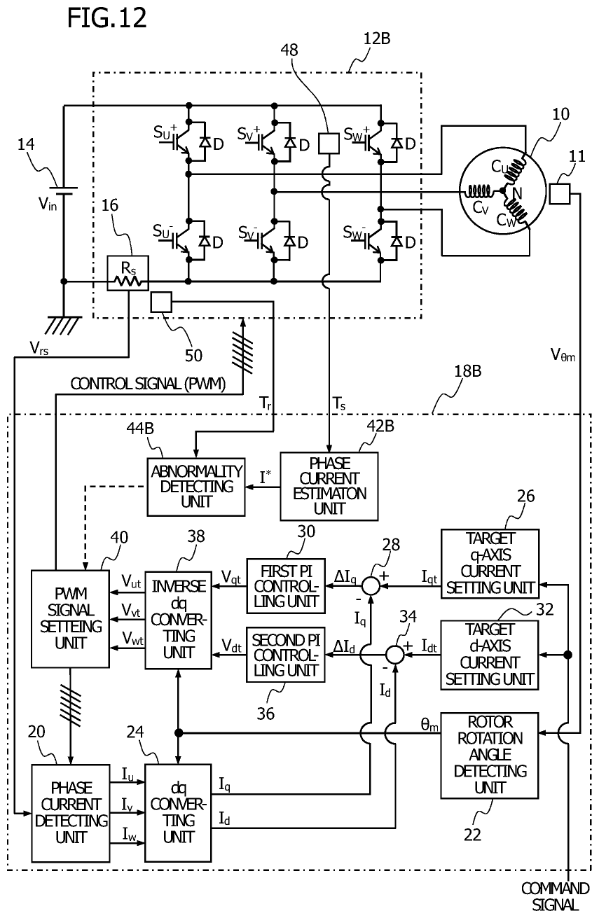

FIG. 12 is a block circuit diagram illustrating an example of a motor system to which an abnormality detecting device for the current sensor 16 according to a third embodiment of the present invention is applied.

As with the second embodiment, an inverter 12B is provided with the first temperature sensor 48 in at least one of the switching elements S_{U}⁺, S_{U}⁻, S_{V}⁺, S_{V}⁻, S_{W}⁺, and S_{W}⁻ or in the vicinity thereof, and the inverter 12B is further provided with the second temperature sensor 50, such as a thermistor, in the current sensor 16 or in the vicinity thereof.

Furthermore, in the third embodiment, one first temperature sensor 48 is provided in the switching element S_{W}⁺ or in the vicinity of the switching element S_{W}⁺ and detects the temperature Ts relating to the switching element S_{W}⁺ for convenience of description.

The second temperature sensor 50 detects the temperature Tᵣ (hereinafter referred to as “temperature relating to the current sensor 16”) of the current sensor 16 or around the current sensor 16. Since the second temperature sensor 50 detects the temperature Tᵣ relating to the current sensor 16, the current sensor 16 is preferably a shunt resistor type current detecting unit in which a temperature change due to energization is relatively remarkable.

In the motor control device 18B, the phase current estimation unit 42B and the abnormality detection unit 44B, which are parts of the motor control device 18B, have a function as an abnormality detecting device for the current sensor 16.

As with the second embodiment, the phase current estimation unit 42B estimates the estimated phase current value I* based on the temperature Ts relating to the switching element S_{W}⁺ detected from an output signal of the first temperature sensor 48. For example, the phase current estimation unit 42B defines the corresponding motor current as the estimated phase current value I* with reference to the sixth current data table based on the temperature Ts relating to the switching element S_{W}⁺ detected by the first temperature sensor 48. Thus, the phase current estimation unit 42A estimates the estimated phase current value I*.

The abnormality detecting unit 44B determines whether the temperature Tᵣ relating to the current sensor 16 detected by the second temperature sensor 50 falls within a normal temperature range to the estimated phase current value I* estimated by the phase current estimation unit 42B, and then detects whether the current sensor 16 is abnormal based on the determination result.

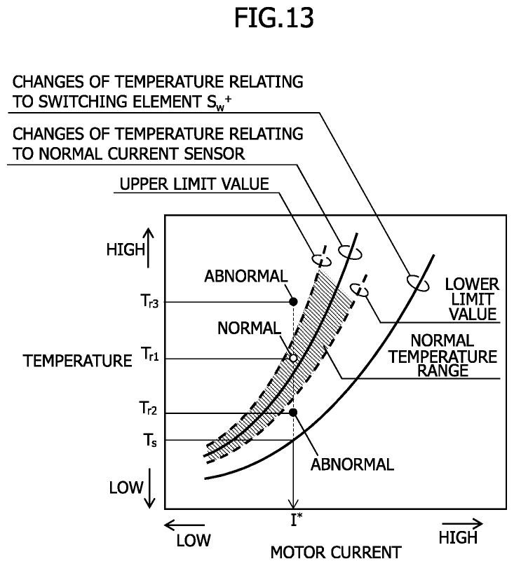

As illustrated in FIG. 13, the above-described normal temperature range is specified (hatched portion in the figure) by pre-digitizing how the temperature relating to the current sensor 16 detected by the second temperature sensor 50 is changed to the motor current when the current sensor 16 is normal by performing an experiment or a simulation and by setting the error range of the upper limit value and the lower limit value of the temperature relating to the current sensor 16 for each motor current in view of variations in the resistance value in the shunt resistor Rs and the like.

For example, the abnormality detecting unit 44B stores, in the ROM or the like, a normal temperature range data table in which the upper limit value and the lower limit value of the temperature relating to the current sensor 16 is associated with the motor current. In this case, the abnormality detecting unit 44B compares the upper limit value and the lower limit value in the corresponding motor current with the temperature Tᵣ relating to the current sensor 16 detected by the second temperature sensor 50, with reference to the normal temperature range data table based on the estimated phase current value I* estimated by the phase current estimation unit 42B, and then, the abnormality detecting unit 44B detects whether the current sensor 16 is abnormal based on the comparison result.

For example, with reference to FIG. 13, when the abnormality detecting unit 44B determines that the temperature Tᵣ relating to the current sensor 16 detected by the second temperature sensor 50 is included in a range between the upper limit value and the lower limit value of the normal temperature range in the motor current which corresponds to the estimated phase current value I*(lower limit value<Tᵣ₁<upper limit value), the abnormality detecting unit 44B detects that the current sensor 16 is normal. On the other hand, when the abnormality detecting unit 44B determines that the temperature Tᵣ relating to the current sensor 16 detected by the second temperature sensor 50 is equal to or lower than the lower limit value (Tᵣ₂≤lower limit value), or equal to or greater than the upper limit value (Tᵣ₃≥upper limit value), the abnormality detecting unit 44B detects that the current sensor 16 is abnormal.

The abnormality detection of the current sensor 16 in the abnormality detecting unit 44B may be performed not only when the motor 10 is rotationally driven, but also before the rotor is rotationally driven as with the second embodiment. When the abnormality detection is performed before the motor 10 is rotationally driven, as with the second embodiment, the abnormality detecting unit 44B forcibly holds the duty of the PWM signals to be output to the switching elements S_{U}⁺, S_{U}⁻, S_{V}⁺, S_{V}⁻, S_{W}⁺, and S_{W}⁻ at a predetermined ratio so that an energization path of the inverter 12B is the same and the level of the motor current to the motor 10 is made constant. The details refer to the description of the second embodiment.

For the estimation of the estimated phase current value I* in the phase current estimation unit 42B, the discharge pressure sensor 7 and the suction pressure sensor 8 used in the first embodiment are not required. Therefore, even in a case in which a driving target of the motor 10 is not the compressor 2 in the refrigeration cycle 1, the abnormality detecting device for the current sensor 16 according to this embodiment is applicable.

Such an abnormality detecting device for the current sensor 16 according to the third embodiment capable of detecting abnormalities of the current sensor 16 even in a case in which the single current sensor 16 is provided in the inverter 12A as with the first embodiment. Moreover, even in a case in which one current sensor is provided for each phase, the abnormality detecting method for the single current sensor 16 of this embodiment is applicable. Thus, the abnormality detection capability is improved as compared with an abnormality detecting device for a current sensor which detects abnormalities by comparing output signals of a plurality of current sensors with each other.

### Fourth Embodiment

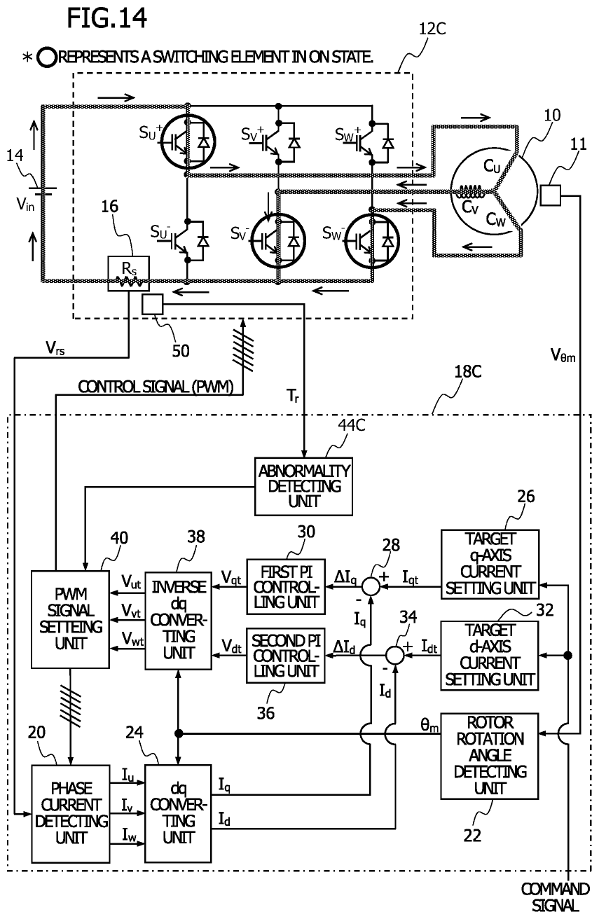

FIG. 14 is a block circuit diagram illustrating an example of a motor system to which an abnormality detecting device for the current sensor 16 according to a fourth embodiment of the present invention is applied.

As with the third embodiment, an inverter 12C is provided with the second temperature sensor 50 which detects the temperature Tᵣ relating to the current sensor 16 in the current sensor 16 or in the vicinity thereof. The current sensor 16 is preferably a shunt resistor type current detecting unit in which a temperature change due to energization is relatively remarkable.

In a motor control device 18C, an abnormality detection unit 44C, which is a part of the motor control device 18C, has a function as an abnormality detecting device for the current sensor 16. In this embodiment, there is no function of estimating the estimated phase current value I* (phase current estimation unit) in contrast to the first to third embodiments. Moreover, the discharge pressure sensor 7 and the suction pressure sensor 8 used for estimating the estimated phase current value I* in the first embodiment are not required, and thus, in a case in which a driving target of the motor 10 is not the compressor 2 in the refrigeration cycle 1, the abnormality detecting device for the current sensor 16 according to this embodiment is applicable.

The abnormality detecting unit 44C detects whether the current sensor 16 is abnormal based on the temperature Tᵣ relating to the current sensor 16 detected by the second temperature sensor 50 in a state in which the energization to the motor 10 is held in a predetermined pattern before the motor 10 is rotationally driven.

In order to hold the energization to the motor 10 in a predetermined pattern, the abnormality detecting unit 44C directs to the PWM signal setting unit 40 to forcibly hold the duty of the PWM signals to be output to the switching elements S_{U}⁺, S_{U}⁻, S_{V}⁺, S_{V}⁻, S_{W}⁺, and S_{W}⁻ at a predetermined ratio irrespective of the U-phase applied setting voltage value Vut, the V-phase applied setting voltage value Vvt, and the W-phase applied setting voltage value Vwt. Thus, an energization path of the inverter 12A is the same and the level of the motor current to the motor 10 is made constant.

For example, as illustrated in FIG. 14, the abnormality detecting unit 44C directs the PWM signal setting unit 40 to hold the duty of the PWM signals to be output to the switching element S_{U}⁺, the switching element S_{V}⁻, and the switching element S_{W} at a predetermined ratio and to hold the duty of the PWM signals to be output to the switching element S_{U}⁻, the switching element S_{V}⁺, and the switching element S_{W}⁺ at 0% (refer to switching pattern No. 4 of FIG. 4).

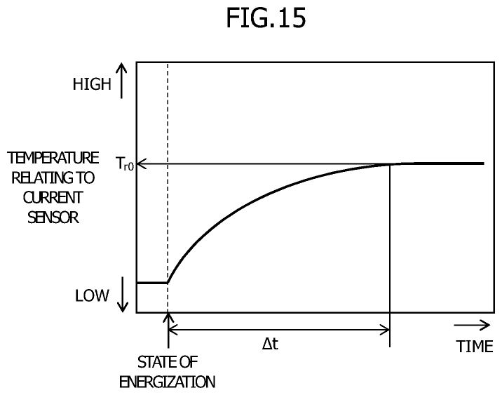

Moreover, as illustrated in FIG. 15, the abnormality detecting unit 44C prestores, by an experiment or a simulation, the temperature relating to the current sensor when a predetermined time Δt has passed, such as when a normal current sensor reaches a thermal equilibrium state, for example, after starting the energization to the motor 10, as a normal temperature Tᵣ₀.

Then, the abnormality detecting unit 44C determines whether the temperature Tᵣ relating to the current sensor 16 detected by the second temperature sensor 50 when the predetermined time Δt has passed after starting the energization to the motor 10 falls within a predetermined range including the normal temperature Tᵣ₀, and then detects whether the current sensor 16 is abnormal based on the determination result.

Such an abnormality detecting device for the current sensor 16 according to the fourth embodiment is capable of detecting abnormalities of the current sensor 16 even in a case in which the single current sensor 16 is provided in the inverter 12C as with the first embodiment. Moreover, even in a case in which one current sensor is provided for each phase, the abnormality detecting method for the single current sensor 16 of this embodiment is applicable. Thus, the abnormality detection capability is improved as compared with an abnormality detecting device for a current sensor which detects abnormalities by comparing output signals of a plurality of current sensors with each other.

In the first to fourth embodiments, the configurations of the motor control devices 18, 18A, 18B, and 18C to which the abnormality detecting device for the current sensor 16 is applied are examples and are not limited to the above-described configurations. For example, the description above is given on the premise that the rotor position θm is detected based on the output signal of the rotational position sensor 11 in the rotor rotation angle detecting unit 22; however, the rotor position Om may be detected based on the applied voltage to each phase and the like without using the rotational position sensor 11. Moreover, although the motor control devices 18, 18A, 18B, and 18C receive electric power from the DC power supply 14, the present invention is not limited thereto and the motor control devices 18, 18A, 18B, and 18C may receive electric power after an output of an alternating-current power supply is rectified in a rectifier circuit (for example, a diode bridge).

In the third embodiment described above, in a case in which the temperature relating to the switching element S_{W}⁺ and the temperature relating to the current sensor 16 similarly change to the motor current when the switching element S_{W}⁺ and the current sensor 16 are normal, the abnormality detecting unit 44B may determine whether a temperature difference between the temperature Ts relating to the switching element S_{W}⁺ detected by the first temperature sensor 48 and the temperature Tᵣ relating to the current sensor 16 detected by the second temperature sensor 50 falls within a predetermined range, and then detect whether the current sensor 16 is abnormal based on the determination result.

### REFERENCE SYMBOL LIST

1 Refrigeration cycle
2 Compressor
7 Discharge pressure sensor
8 Suction pressure sensor
10 Motor
12, 12A, 12B, 12C Inverter
16 Current sensor
18, 18A, 18B, 18C Motor control device
20 Phase current detecting unit
40 PWM signal setting unit
42, 42A, 42B Phase current estimation unit
44, 44A, 44B, 44C Abnormality detecting unit
46 Rotational speed detecting unit
48 First temperature sensor
50 Second temperature sensor
Iu, Iv, Iw Phase current
I* Estimated phase current value
ω Rotational speed
Po Detected value of discharge pressure
Pi Detected value of suction pressure
Ts Temperature relating to switching element S_{W}⁺
Tr Temperature relating to current sensor

1. An abnormality detecting device for a current sensor detecting whether the current sensor provided in an inverter which supplies electric power to a motor driving a compressor is abnormal, the abnormality detecting device for the current sensor comprising:
a phase current detecting unit which detects a phase current of the motor based on an output signal of the current sensor;
an estimation unit which estimates the phase current based on at least one of a discharge pressure and a suction pressure of the compressor and a rotational speed of the motor; and
an abnormality detecting unit which compares a detected value of the phase current detected by the phase current detecting unit with an estimated value of the phase current estimated by the estimation unit, and then detects whether the current sensor is abnormal based on a result of the comparison.

2. An abnormality detecting device for a current sensor detecting whether a current sensor provided in an inverter which supplies electric power to a motor is abnormal, the abnormality detecting device for the current sensor comprising:
a phase current detecting unit which detects a phase current of the motor based on an output signal of the current sensor;
an estimation unit which estimates the phase current based on an output signal of a first temperature sensor provided in a switching element of the inverter or in the vicinity of the switching element; and
an abnormality detecting unit which compares a detected value of the phase current detected by the phase current detecting unit with an estimated value of the phase current estimated by the estimation unit, and then detects whether the current sensor is abnormal based on a result of the comparison.

3. An abnormality detecting device for a current sensor detecting whether a current sensor provided in an inverter which supplies electric power to a motor is abnormal, the abnormality detecting device for the current sensor comprising:
an estimation unit which estimates a phase current of the motor based on an output signal of a first temperature sensor provided in a switching element of the inverter or in the vicinity of the switching element; and
a detecting unit which detects whether the current sensor is abnormal based on an estimated value of the phase current estimated by the estimation unit and a temperature relating to the current sensor detected based on an output signal of a second temperature sensor provided in the current sensor or in the vicinity of the current sensor.

4. An abnormality detecting device for a current sensor detecting whether a current sensor provided in an inverter which supplies electric power to a motor is abnormal, the abnormality detecting device for the current sensor comprising:
a detecting unit which detects whether the current sensor is abnormal based on a temperature relating to the current sensor detected based on an output signal of a temperature sensor provided in the current sensor or in the vicinity of the current sensor in a state in which energization to the motor is held in a predetermined pattern before the motor is rotationally driven.
